(19) United States
(12) Patent Application Publication
(10) Pub. No.: US 2008/0074908 A1
(43) Pub. Date: Mar. 27, 2008

(54) Depletion mode transistor as a start-up control element

(75) Inventors: Kuang-Ming Chang, ChungLi City (TW); Shien-Hsing Cheng, Taipei (TW)

Correspondence Address: TUNG & ASSOCIATES, Suite 120, 838 W. Long Lake Road, Bloomfield Hills, MI, 48302, US

(73) Assignee: Richtek Technology Corporation

(21) Appl. No.: 11/714,474

(22) Filed: Mar. 5, 2007

(30) Foreign Application Priority Data
Sep. 22, 2006 (TW) 095135095

(51) Int. Cl. H02M 1/00; H01L 29/808

(52) U.S. Cl. 363/49; 257/272; 257/E29.312

(57) ABSTRACT

A depletion mode transistor serving as a start-up control element is provided. The depletion mode transistor includes a first depletion mode junction transistor and a second depletion mode transistor. The first depletion mode junction transistor includes a source and a drain, one of which is coupled to a voltage supply source, and a gate electrically coupled to ground. The second depletion mode transistor includes a source and a drain, one of which is coupled to the other one of the source and the drain of the first depletion mode junction transistor, and

a gate being controllable to turn OFF the second depletion mode transistor.

### BACKGROUND

1. Field of Invention

The present invention relates to a depletion mode transistor serving as a start-up control element. More particularly, the present invention relates to a depletion mode field-effect transistor (FET) serving as a start-up device of a power circuit without complicated circuit structure.

2. Description of Related Art

A start-up circuit is often required when a power supply circuit supplies voltage to a power circuit within an integrated circuit (IC). The start-up circuit provides a starting bias voltage until the power circuit is able to function regularly. Afterwards, the start-up circuit is expected to be idle and consume no power, if ideally. FIG. 1 is a diagram illustrating relationships among a start-up circuit 10, a power supply 100 and a power circuit 200. During initialization stage, the power circuit 200 has not been provided with power yet. Therefore, it is necessary to provide a start-up circuit 10 to charge the capacitor C until the voltage at the node Vbias reaches a predetermined value that is able to turn ON the power circuit 200. After the power circuit 200 is turned ON, it may operate without aid from the start-up circuit 10. For example, the power circuit 200 may obtain power from the power supply 100 via some other approach and transfer the power into a low DC voltage Vdd required by the IC. The details are not described here for that they are well known to those skilled in the art.

FIG. 2 is a diagram illustrating a prior art start-up circuit 10. Since the start-up circuit 10 is expected to consume as little current as possible, the simplest approach to implement the star-up circuit is to provide a resistor 20 of high resistance. The resistor 20 transfers the voltage from the power supply 100 to a low current, charging the capacitor C until the node Vbias reaches a predetermined voltage value. The voltage at the node Vbias, for example, may be provided to drive a pulse width modulation (PWM) circuit 12 in the power circuit 200, and the power circuit operates under the control of the PWM circuit 12. The details of the PWM circuit and how it controls the power circuit 200 are not described here for that they are well known to those skilled in the art.

According to the prior art illustrated in FIG. 2, the resistance of the resistor 20 must be quite large to limit the current, because the voltage provided by the power supply 100 is quite high. Accordingly, the area of the resistor 20 inevitably becomes very large, and a huge amount of heat is generated. Moreover, such start-up circuit cannot be turned OFF; the serious problems of power consumption and heat generation go on even after the power circuit has been started up.

Another start-up circuit is disclosed in U.S. Pat. No. 5,285,369 “Switched Mode Power Supply Integrated Circuit with Start up Self Biasing”. The disclosed circuit is very complicated, and a simplified form thereof is illustrated in FIG. 3. This prior art utilizes the characteristics of the parasitic junction transistor inherently existing with a metal-oxide-semiconductor field-effect transistor (MOSFET). As shown in the figure, the MOSFET 84 maybe taken as a combination of a junction field-effect transistor (JFET) 86 and a MOSFET 88. The JFET 86 is a depletion mode transistor, inherently capable of limiting current, and it is normally in an ON state as its gate is electrically connected to ground. The node between the JFET 86 and the MOSFET 88 provides current for starting up a control circuit 14. The control circuit 14 provides two functions: on the one hand, the control circuit 14 charges the capacitor C; on the other hand, when a voltage at the node Vbias reaches a predetermined value, the control circuit 14 generates a control signal to switch off the MOSFET 88 and turn off the start-up circuit formed by the MOSFET 84 and the control circuit 14.

Though the conventional start-up circuit illustrated in FIG. 3 can be automatically turned off and the heat generated by the circuit is much less than that in FIG. 2, the structure of the control circuit 14 is still too complicated(as may be understood by referring to the details thereof), which is undesired.

Therefore, another circuit structure is disclosed in U.S. Pat. No. 5,477,175 “Off-Line Bootstrap Start up Circuit”, which is simpler than the circuit in FIG. 3. As illustrated in FIG. 4, the circuit disclosed in U.S. Pat. No. 5,477,175 obtains current from the node between the JFET 101 and the MOSFET 102, and transfers the current to voltage by a resistor 103, which is supplied to the gate of the MOSFET 102 to turn ON the MOSFET 102. The resistor 103 needs not be too large since it only has to provide a voltage high enough for turning ON the MOSFET 102. Hence the problem of heat generation is less severe. After the power circuit 200 is started, the transistor 109 can be switched OFF by controlling the node 113. That is, the current flowing through the resistor 103 is turned OFF.

Though the complexity of the circuit illustrated in FIG. 4 is reduced as compared to the circuit disclosed in U.S. Pat. No. 5,285,369, it is still not satisfactory because it utilizes a resistor.

In view of the foregoing, it is desired to provide an advanced start-up circuit which has a simple circuit structure, employing a depletion mode transistor, to avoid the drawbacks in the prior art.

### SUMMARY

It is therefore an aspect of the present invention to provide a depletion mode transistor serving as a start-up control element, which provides the function of a start-up circuit with a simple structure.

It is a second aspect of the present invention to provide a start-up circuit.

It is a third aspect of the present invention to provide a semiconductor device as a start-up control element.

In accordance with the foregoing and other objectives of the present invention, and as disclosed by one embodiment of the present invention, a depletion mode transistor serving as a start-up control element comprises a first depletion mode junction transistor including a source and a drain, one of which is coupled to a power supply, and a gate coupled to ground; and a second depletion mode transistor including a source and a drain, one of which is coupled to the other one of the source and the drain of the first depletion mode junction transistor, and a gate controllable to turn OFF the second depletion mode transistor.

In the embodiment above, preferably, the second depletion mode transistor is a junction transistor.

Further, in accordance with another embodiment of the present invention, a start-up circuit is provided. The start-up circuit comprises a first transistor normally in an ON state, and a second depletion mode transistor coupled to the first transistor in series, the second depletion mode transistor being normally in an ON state and able to be turned OFF.

In accordance with yet another embodiment of the present invention, a semiconductor device comprises a substrate of a first conductivity type, a first well and a second well separated from each other, wherein both of the first well and the second well are of a second conductivity type, and the two wells are normally conductive to each other, a third well of the first conductivity type, located between the first well and the second well, and a fourth well of the first conductivity type, being separated from the third well and conductive to the substrate. The semiconductor device serves as a start-up control element.

It is to be understood that both the foregoing general description and the following detailed description are provided as examples, for illustration rather than limiting the scope of the invention.

### BRIEF DESCRIPTION OF THE DRAWINGS

These and other features, aspects, and advantages of the present invention will become better understood with regard to the following description, appended claims, and accompanying drawings where:

FIG. 1 is a diagram showing a typical structure of a start-up circuit;

FIG. 2 is a circuit diagram of a conventional start-up circuit having a resistor;

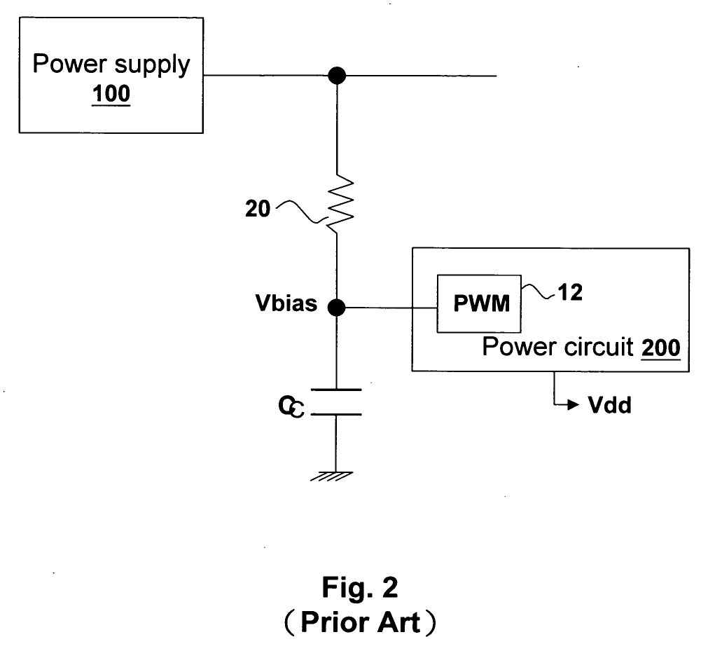

FIG. 3 is a circuit diagram showing another prior art start-up circuit;

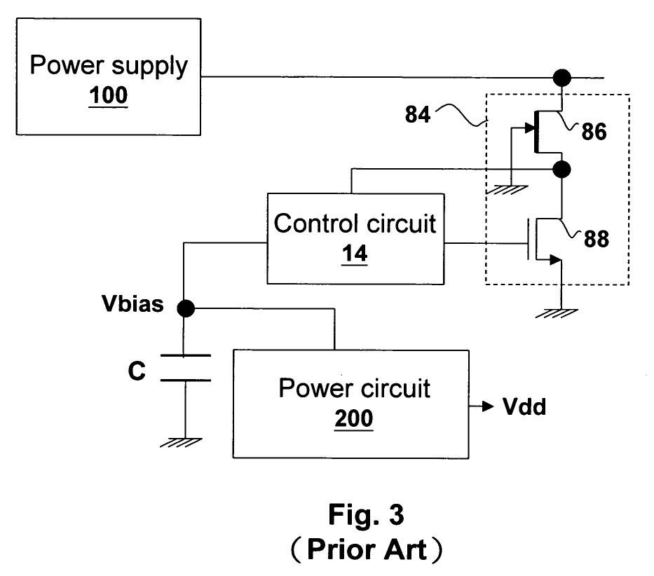

FIG. 4 is a circuit diagram showing yet another prior art start-up circuit;

FIG. 5 is a circuit diagram showing an embodiment of the present invention;

FIG. 6 is a semiconductor cross-sectional diagram of an embodiment of the present invention; and

FIG. 7 is a semiconductor cross-sectional diagram of another embodiment of the present invention.

### DESCRIPTION OF THE PREFERRED EMBODIMENTS

The drawings as referred to throughout the description of the present invention are for illustration only, but not drawn according to actual scale.

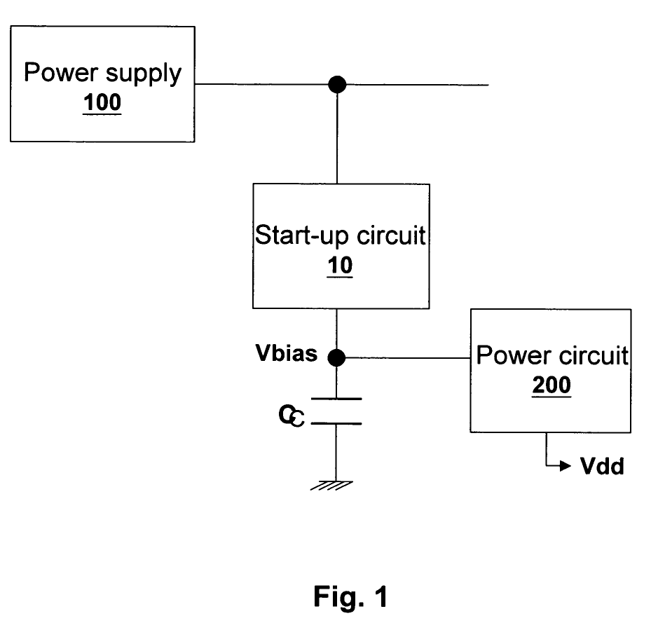

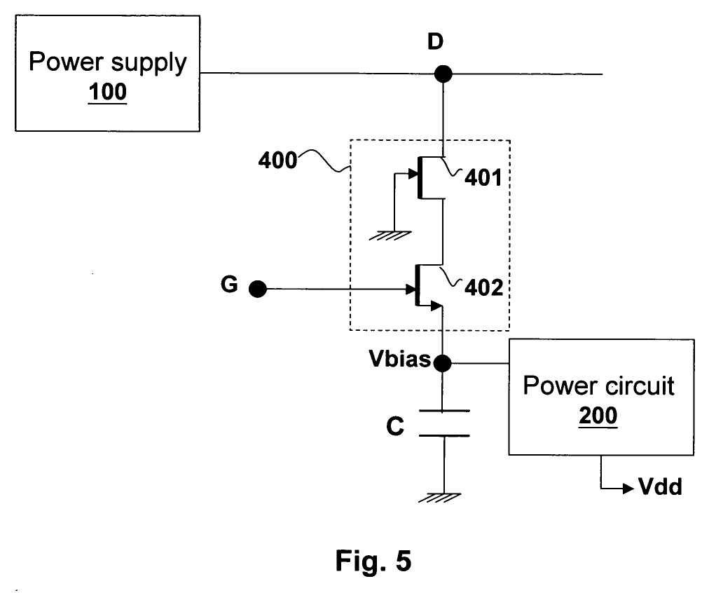

FIG. 5 is a schematic circuit diagram illustrating an embodiment of the present invention. As shown in FIG. 5, in the present embodiment, a depletion mode transistor 400 is provided between the power supply 100 and the power circuit 200 to form the start-up circuit. In the present embodiment, the transistor 400 is a depletion mode FET, of which an equivalent circuit is as illustrated in FIG. 1, including a depletion mode junction field-effect transistor (JFET) 401 and a depletion mode field-effect transistor (FET) 402. In one preferred embodied form, the depletion mode JFET 401 is a high-voltage device, while the depletion mode FET 402 may be a low-voltage device. The “high-voltage” corresponds to the voltage provided by the power supply 100, while the “low-voltage” is a voltage relatively lower than the “high-voltage”.

Referring to FIG. 5, the depletion mode JFET 401 is kept in an ON state with the gate of the depletion mode JFET 401 being electrically coupled to ground. Being a depletion mode JFET, the current flowing through the depletion mode JFET 401 is limited inherently, achieving the low current function required by the start-up circuit. One feature of the present invention is that the FET 402 is a depletion mode transistor as well. A gate node G thereof may be coupled to an internal control node (not shown) of the power circuit 200. In the initialization stage, there is no voltage at the gate node G since there is no current in the power circuit 200. Hence the gate node G is substantially equivalent to being grounded. Therefore, the depletion mode FET 402 is conductive and passes current from the depletion mode JFET 401 to the power circuit 200. When the power circuit 200 has been started up, there is current generated internally. The gate node G may be controlled thereby to turn OFF the depletion mode FET 402 for saving power.

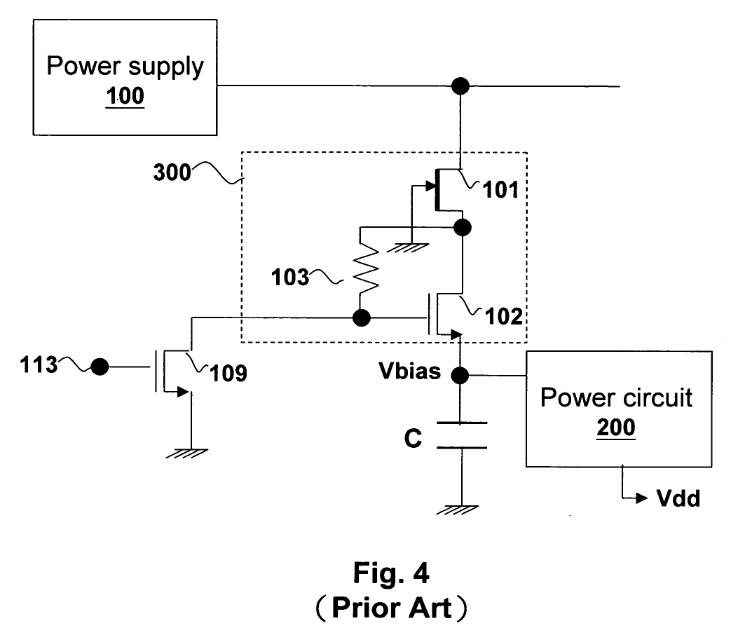

In the aforementioned circuit, no complicated control scheme is required. The circuit structure is more concise than the conventional circuit illustrated in FIG. 4. Besides, there is no resistor adopted in the start-up circuit in the aforementioned embodiment of the present invention. Hence there is no heat dissipation problem in the present invention.

The depletion mode FET 402 may be a MOSFET or a junction transistor, in which a junction transistor is preferred for that its control gate is a P/N junction which is capable of sustaining a higher reverse breakdown voltage. Besides, compared to the MOSFET, the P/N junction between a gate and a source may provide a better ESD protection. For the above reasons, in the preferred embodiment shown in the circuit diagram of FIG. 5, the FET 402 is a junction field-effect transistor, as a preferred example but not a limitation to the FET 402. Please note that other types of depletion mode transistors are within the scope of the present invention.

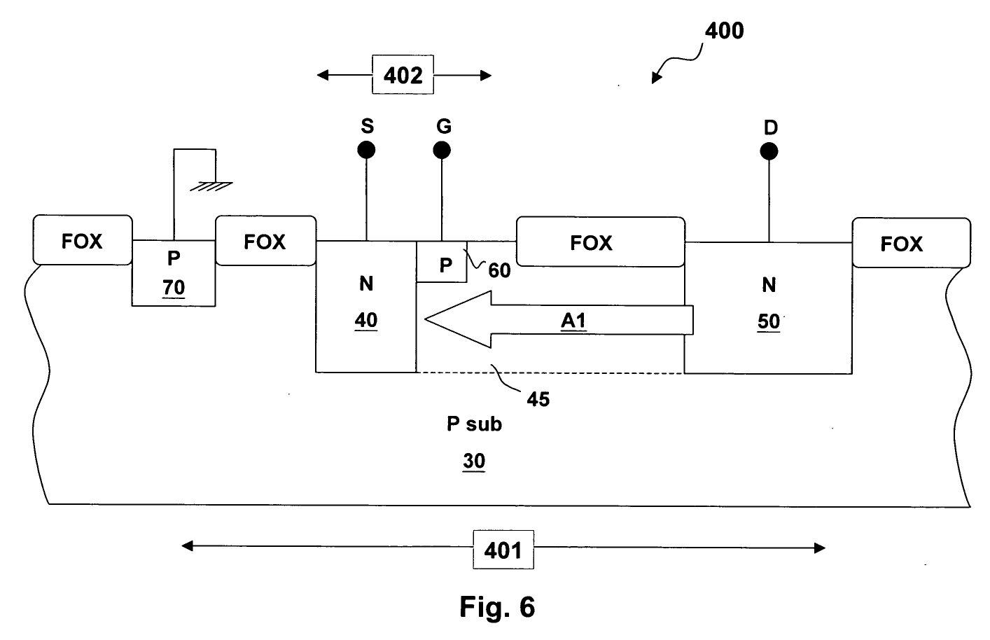

FIG. 6 is a simplified semiconductor cross-sectional diagram embodying the aforementioned circuit according to an embodiment of the present invention. As illustrated in FIG. 6, an N-type well 40 and an N-type well 50 are provided in a P-type substrate 30, as the source region and the drain region of the depletion mode transistor 400 respectively, or more specifically, as the source region of the FET 402 and the drain region of the JFET respectively. The N-type well 40 and the N-type well 50 are respectively coupled to the Vbias and the power supply 100 in FIG. 5 via the source node S and the drain node D. Due to the difference between the electrical potentials of the drain node D and the source node S, and the drift and the diffusion of the doped impurities, there are N-type impurities existing in the region 45 between the N-type well 40 and the N-type well 50, as shown by the arrow A1. The region 45 is equivalent to the source region of the JFET 401 and the drain region of the FET 402. That is, the source region of the JFET 401 and the drain region of the FET 402 are electrically connected to each other. In fact, the drain region 45 and the source region 40 of the FET 402 are conductive to each other. However, the conduction may be pinched-off by biasing the P-type well 60. In other words, the N-type well 40, the P-type well 60 and the drift region 45 of N-type impurities together form a depletion mode junction transistor, that is, the FET 402 in FIG. 5.

Besides, there is a P-type well 70 near the FET 402 on the substrate 30. The P-type well 70 serves as the gate of the JFET 401 in FIG. 5. The P-type well 70 is electrically coupled to the substrate 30. Therefore, the drift region 45 of N-type impurities, the P-type well 70 (the substrate 30) and the N-type well 50 together serve as a depletion mode junction transistor, that is, the JFET 401 in FIG. 5.

Of course, in the aforementioned semiconductor structure, there should be oxides to separate the active regions, as shown by the field oxides (FOX) in the drawing.

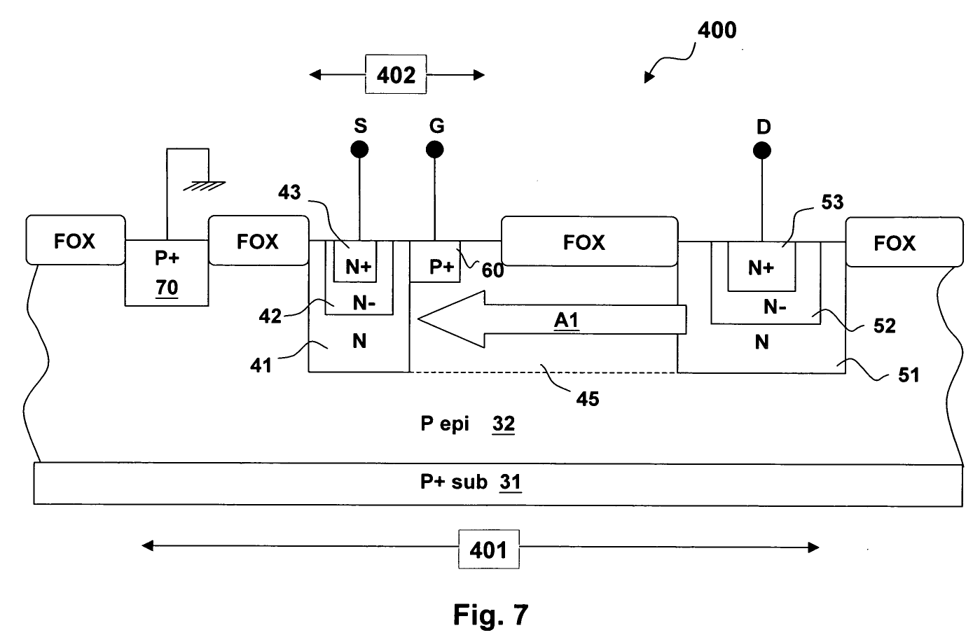

FIG. 7 is a semiconductor cross-sectional diagram illustrating another preferred embodiment of the aforementioned circuit of the present invention. Referring to FIG. 7, the P-type substrate 30 may include a heavily-doped body 31 and an epitaxy growth layer 32 doped with P-type impurities. The N-type well 40 and the N-type well 50 may include an N-type well 41 and an N-type well 51, a lightly-doped N-type region 42 and a lightly-doped N-type region 52, and a heavily-doped N-type region 43 and a heavily-doped N-type region 53, respectively. Each of the P-type well 60 and the P-type well 70 may be a heavily-doped well. The aforementioned semiconductor structure may be taken as a preferred embodiment which forms a better transistor device.

As described above, the primary feature of the present invention is to use a depletion mode transistor as the control element of a start-up circuit. Since the depletion mode transistor is normally in an ON state and the current flowing through is limited inherently, the basic requirements of the start-up circuit are met. In the initialization stage of a power circuit electrically connected with the start-up circuit, the depletion mode transistor is normally in an ON state. However, after the power circuit has been started and capable of providing electric power internally, the depletion mode transistor may be turned OFF thereby. Although the present invention has been described in considerable detail with reference to certain preferred embodiments thereof, other embodiments are possible. Some of the examples are listed below: the start-up circuit is not limited to starting up a power circuit, but may be employed to start up other circuits in other applications; the mechanism to start up the power circuit 200 is not limited to charging the capacitor; the internal structure of the power circuit 200 may be varied and different; the well structures, the doping densities and the arrangement of the field oxides of the semiconductor can be varied and different, etc. In view of the foregoing, it is intended that the present invention cover all such modifications and variations, which should interpreted to fall within the scope of the following claims and their equivalents.

What is claimed is:

1. A start-up control element, comprising:
a first depletion mode junction transistor including:
a source and a drain, one of which is coupled to a power supply; and
a gate being grounded; and
a second depletion mode transistor including:
a source and a drain, one of which is coupled to the other one of the source and the drain of the first depletion mode junction transistor; and
a gate being controllable to turn OFF the second depletion mode transistor.

2. The start-up control element of claim 1, wherein the second depletion mode transistor is a junction transistor.

3. The start-up control element of claim 1, wherein the other one of the source and the drain of the second depletion mode transistor is coupled to a capacitor.

4. The start-up control element of claim 1, wherein the start-up control element forms a start-up circuit for starting up a power circuit.

5. The start-up control element of claim 1, wherein the first depletion mode junction transistor is a high voltage device, and the second depletion mode transistor is a low voltage device.

6. A start-up circuit comprising:
a first transistor being normally in an ON state; and
a second depletion mode transistor coupled to the first transistor in series, the second depletion mode transistor being normally in an ON state and able to be turned off.

7. The start-up circuit of claim 6, wherein the second transistor is a depletion mode field effect transistor, which can be turned off by controlling its gate.

8. The start-up circuit of claim 6, wherein the first transistor is a depletion mode junction transistor.

9. The start-up circuit of claim 6, wherein the first transistor and the second transistor are both depletion mode junction transistors.

10. The start-up circuit of claim 6, wherein the first transistor is a high voltage device, and the second depletion mode transistor is a low voltage device.

11. The start-up circuit of claim 6, wherein the first transistor and the second transistor are integrated into an integral device by a semiconductor process.

12. The start-up circuit of claim 6 being coupled between a power supply and a capacitor.

13. A semiconductor device comprising:
a substrate of a first conductivity type;
a first well and a second well separated from each other, wherein both of the first well and the second well are of a second conductivity type, and the two wells are normally conductive to each other;
a third well of the first conductivity type, located between the first well and the second well; and
a fourth well of the first conductivity type, being separated from the third well and conductive to the substrate,
wherein the semiconductor device serves as a start-up control element.

14. The semiconductor device of claim 13, wherein the first conductivity type is P-type, and the second conductivity type is N-type.

15. The semiconductor device of claim 13, wherein the third well is controllable to turn off the conduction between the first well and the second well.

16. The semiconductor device of claim 13, wherein the fourth well is grounded.

17. The semiconductor device of claim 13, wherein the substrate includes a body and an epitaxy growth layer.

18. The semiconductor device of claim 13, wherein the first well and the second well each includes at least a heavily-doped region and a lightly-doped region.
